(19) United States
(12) Patent Application Publication
(10) Pub. No.: US 2021/0265674 A1
(43) Pub. Date: Aug. 26, 2021

(54) METHOD AND DETECTOR FOR DETECTING INHOMOGENEOUS CELL PERFORMANCE OF A BATTERY SYSTEM

(71) Applicant: SAMSUNG SDI CO., LTD., Yongin-si (KR)

(72) Inventor: Stefan DOCZY, Yongin-si (KR)

(21) Appl. No.: 17/181,369

(22) Filed: Feb. 22, 2021

(30) Foreign Application Priority Data
Feb. 25, 2020 (EP) 20159189.8
Feb. 18, 2021 (KR) 10-2021-0022069

(51) Int. Cl. H01M 10/42; H02J 7/00; G01R 31/392; G01R 31/396; G01R 31/3835; G01R 31/374; B60L 50/60; B60L 58/12; B60L 58/16

(52) U.S. Cl. CPC H01M 10/4285; H02J 7/005; G01R 31/392; G01R 31/396; H01M 2220/20; G01R 31/374; B60L 50/60; B60L 58/12; B60L 58/16; G01R 31/3835

(57) ABSTRACT

A method, including: determining a charging resistance ratio as a ratio of a maximum cell charging resistance of a battery cell among a plurality of battery cells and an average cell charging resistance of the battery cells, determined in response to an applied charging current; and/or determining a discharging resistance ratio as a ratio of a maximum cell discharging resistance of a battery cell among the battery cells and an average cell discharging resistance of the battery cells, determined in response to an applied discharging current; and determining the battery system is in a degraded ageing state when at least one of the charging resistance ratio and/or the discharging resistance ratio is above a threshold value; and determining the battery system is in a non-degraded ageing state when none of the charging resistance ratio and/or the discharging resistance ratio is above the threshold value.

### CROSS-REFERENCE TO RELATED APPLICATION

European Patent Application No. 20159189.8, filed on Feb. 25, 2020, in the European Intellectual Property Office, and entitled: “Method and Detection Unit for Detecting Inhomogeneous Cell Performance of a Battery System,” and Korean Patent Application No. 10-2021-0022069, filed on Feb. 18, 2021, are incorporated by reference herein in their entireties.

### BACKGROUND

### 1. Field

Embodiments relate to a method and a detector for detecting inhomogeneous cell performance of a battery system, and an electrical vehicle with the detector.

### 2. Description of the Related Art

In recent years, vehicles have been developed using electric power as a source of motion. An electric vehicle is an automobile that is powered by an electric motor using energy stored in rechargeable batteries. An electric vehicle may be solely powered by batteries or may be a form of hybrid vehicle powered by, e.g., a gasoline generator. Furthermore, the vehicle may include a combination of electric motor and combustion engine. In general, an electric-vehicle battery (EVB) or traction battery is a battery used to power the propulsion of battery electric vehicles (BEVs). Electric-vehicle batteries differ from starting, lighting, and ignition batteries because they are designed to give power over sustained periods of time. A rechargeable or secondary battery differs from a primary battery in that it can be repeatedly charged and discharged, while the latter provides only an irreversible conversion of chemical to electrical energy. Low-capacity rechargeable batteries are used as power supply for small electronic devices, such as cellular phones, notebook computers and camcorders, while high-capacity rechargeable batteries are used as the power supply for hybrid vehicles and the like.

Rechargeable batteries may be used as a battery module formed of a plurality of unit battery cells coupled in series and/or in parallel so as to provide a high energy density, in particular for motor driving of a hybrid vehicle. A battery module may be formed by interconnecting the electrode terminals of the plurality of unit battery cells depending on a intended amount of power and in order to realize a high-power rechargeable battery. The cells can be connected in series, parallel or in a mixture of both to deliver the desired voltage, capacity, or power density. Components of battery packs include the individual battery modules and the interconnects, which provide electrical conductivity between them.

### SUMMARY

Embodiments are directed to a method for detecting inhomogeneous cell performance of a battery system having a plurality of battery cells, the method including: determining a charging resistance ratio, which is a ratio of a maximum cell charging resistance of a battery cell among the plurality of battery cells and an average cell charging resistance of the plurality of battery cells, each determined in response to a charging current applied to the plurality of battery cells; and/or determining a discharging resistance ratio, which is a ratio of a maximum cell discharging resistance of a battery cell among the plurality of battery cells and an average cell discharging resistance of the plurality of battery cells, each determined in response to a discharging current applied to the plurality of battery cells; and determining that the battery system is in a degraded ageing state when at least one of the determined charging resistance ratio and/or the determined discharging resistance ratio is above a predetermined threshold value; and determining that the battery system is in a non-degraded ageing state when none of the determined charging resistance ratio and/or the determined discharging resistance ratio is above the predetermined threshold value.

The predetermined threshold value may be above 1, e.g., set to 2 or may also be, e.g., 1.5 or 2.5, but embodiments may use a different threshold value. The number of battery cells may be 6, 12, 16, 24, but also here embodiments may use a different number. Averages throughout the application may be, e.g., arithmetic averages. A ratio is in other words a division. An inhomogeneous cell performance may be present when one or a small fraction of battery cells have a higher internal resistance than a majority of the battery cells.

The used resistance ratios may provide for highly sensitive detection of rapid ageing of an individual battery cell or a small group of cells among a plurality of cells, e.g., due to high local temperature exposure or self-discharge, e.g., due to metallic contamination or dendrites growth caused by lithium plating. Thus, inhomogeneous cell performance may be readily detected and the error mode(s) identified. Further, embodiments may provide for identifying ageing in charging and discharging directions. For example, a discharging resistance ratio may be within the allowable range or vice versa, but the charging resistance ratio may already be above the threshold such that early identification is provided. An embodiment using the resistance ratio may provide for enhanced diagnosis, as the determination may be performed with higher frequency and the ratio may be more robust by permitting a wider current and temperature range while still providing sufficient accuracy compared to a general procedure in which only the internal resistance is used to determine ageing. Thus, if due to high cell resistance the current is limited, a resistance ratio according to an embodiment may still be determined even if current conditions for determination of cell resistances are not fulfilled. Embodiments may be suitable for a field application.

In an example embodiment, the determining of the charging resistance ratio may be based on a determined average cell voltage, a determined average open circuit voltage, and a determined maximum cell voltage among a plurality of cell voltages of the battery system, and the determining of the discharging resistance ratio may be based on the determined average cell voltage, the determined average open circuit voltage, and a determined minimum cell voltage among the plurality of cell voltages of the battery system. The determination may be based on cell voltages, only, and even if current conditions for cell resistance determination are not fulfilled, the above determination may still be performed thus, e.g., improving availability.

In an example embodiment, the average open circuit voltage may be determined based on a determined average state of charge. The average state of charge may be readily determined to determine the average open circuit voltage of the battery cells.

In an example embodiment, determining the maximum cell voltage, the average cell voltage and the minimum cell voltage may be based on measured individual cell voltages of the battery cells. The individual voltages may be determined, e.g., by voltage sensors. The average may be determined by determination of the arithmetic mean of the cell voltages. Maximum and minimum cell voltage may, e.g., be retrieved from a vector including all measured cell voltages. The measurement of the cell voltages may be synchronously performed, e.g., within a time window of 100 ms, but shorter or longer time windows may be employed.

In an example embodiment, determining a charging resistance ratio may include calculating the fraction (uCellMax−uOCV)/(uCellAvg−uOCV) and/or wherein determining the discharging resistance ratio may include calculating the fraction (uOCV−uCellMin)/(uOCV−uCellAvg), wherein: uCellMax is the determined maximum cell voltage, uOCV is the determined average open circuit voltage, uCellAvg is the determined average cell voltage, and uCellMin is the determined minimum cell voltage. The determination may not directly require the charging current or the discharging current, and thus may be more robust with respect to lower currents or irregular current pulses.

In an example embodiment, the method may include determining at least one influence quantity for the determination of the charging resistance ratio and/or the discharging resistance ratio, and determining if the at least one influence quantity fulfills a limit condition, and performing the operations of determining that the battery system is in a non-degraded state or in a degraded state only if the limit condition is fulfilled. Reliability of the determination may be increased leading to a robust determination of ageing. An influence quantity is referred to as a quantity that affects the quality of the determination of the particular resistance ratios. An unnecessary exchange of the battery system in response to a wrong determination may thereby prevented, and validation of the determination may be provided.

In an example embodiment, the influence quantity may be an integrated current, and a limit condition may be fulfilled when a determined integrated charging current is equal to or above a charging current limit and/or when an integrated discharging current is equal or below an integrated discharging current limit. A defined state of the battery system may be reached by fulfilling the criterion before evaluating the measurement. Also, before evaluating the measurement, sufficient charge reversal may have occurred to improve determination quality.

In an example embodiment, the influence quantity may be a determined charging current and/or discharging current, and the limit condition may be fulfilled when the modulus of the determined current is between a lower current limit and an upper current limit. In comparison to mere resistance measurement, the lower current limit may be set substantially lower as the present determination of the resistance ratio may be more robust towards small currents and/or irregular current pulses. For example, the lower current limit may be 10 A or even less or 5 A or less. Such limit may still generate significant voltage response. For example, the maximum discharge current may be approximately 300 A, the maximum charge current may be approximately 200 A, a single cell resistance approximately 1.5 mOhm.

In an example embodiment, the influence quantity may be a determined average state of charge, and the limit condition may be fulfilled when the determined average state of charge is between a lower state of charge limit and an upper state of charge limit. An upper state of charge limit may be, e.g., 90%, or 80%, and a lower average state of charge ratio may be 10% or 20%. Such boundary values may help to ensure a high measurement precision for determining inhomogeneous cell performance.

In an example embodiment, the influence quantity may be a determined average temperature, and the limit condition may be fulfilled when the average temperature is between a lower temperature limit and an upper temperature limit. A lower temperature limit may be, e.g., −20° C. or −10° C., but the limit may be varied. An upper temperature limit may be, e.g., 50° C. For too high average temperatures, the battery cells may be homogeneously affected and individual weakly performing cells may not be sufficiently detectable. The average may help ensure that despite a local high temperature at a single cell or a small group of cells, the average temperature may still fulfil the condition.

In an example embodiment, the influence quantity may be a first charging voltage difference between the minimum cell voltage among a plurality of cell voltages of the battery system and the average open circuit voltage upon charging and/or a second discharging voltage difference between the average open circuit voltage upon discharging and the maximum cell voltage among a plurality of cell voltages, and the limit condition may be fulfilled when the first charging voltage difference is above a first charging voltage difference limit and/or the second discharging voltage difference is above a second discharging voltage difference limit. The condition may help ensure that inhomogeneous behavior can be detected. The criterion may include that discharging and charging cause different response, and thus actually the fulfilment of two criteria may be checked. The voltage difference limits for the cell voltage spread may be about 50 mV, 30 mV or 20 mV.

In an example embodiment, the determining of the charging resistance ratio and/or the discharging resistance ratio may be repeated at every drive cycle. Thereby, observation can be done with high frequency and weak performance of individual cells be rapidly detected.

Embodiments are also directed to a detector for detecting inhomogeneous cell performance of a battery system having a plurality of battery cells. The detector may be configured to perform the above described method according to the various embodiments. A detector may, e.g., be a processor, e.g., a microprocessor, a processor or a CPU, or the like. The detector may include suitable means to perform the corresponding method operations.

The detector may include a determiner configured to determining a charging resistance ratio, which is the ratio of a maximum cell charging resistance of a battery cell among a plurality of battery cells and an average cell charging resistance of the plurality of battery cells, each determined in response to a charging current applied to the battery cells; and/or configured to determining a discharging resistance ratio, which is the ratio of a maximum cell discharging resistance of a battery cell among a plurality of battery cells and the average cell discharging resistance of the battery cells, each determined in response to a discharging current applied to the battery cells. The detector may further include a diagnoser configured to determine that the battery system is in a degraded ageing state when at least one of the determined charging resistance ratio and/or the determined discharging resistance ratio is above a predetermined threshold value; and configured to determine that the battery system is in a non-degraded ageing state when none of the determined charging resistance ratio and/or the determined discharging resistance ratio is above the predetermined threshold value.

In an example embodiment, the detector further includes a condition checker configured to determine at least one influence quantity for the determination of the charging resistance ratio and/or the discharging resistance ratio, and transmit a control signal to the diagnoser indicative of if the at least one influence quantity fulfills a limit condition. The diagnoser may be configured to perform the operations of determining that the battery system in a non-degraded state or in a degraded state only when the control signal is indicating that the limit condition is fulfilled. Thus, accuracy of the measurement using the resistance ratio may be enhanced.

Embodiments are also directed to a battery system, including a plurality of battery cells and a detector according to an embodiment.

Embodiments are also directed to a battery system according to an embodiment.

### BRIEF DESCRIPTION OF THE DRAWINGS

Features will become apparent to those of skill in the art by describing in detail example embodiments with reference to the attached drawings in which:

FIG. 1 illustrates a method and a detector according to an example embodiment;

FIGS. 2 to 9 illustrate the method and condition check sub elements performing particular condition tests according to example embodiments; and

FIG. 10 schematically illustrates a battery system according to an example embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey example implementations to those skilled in the art. In the drawing figures, the dimensions of layers and regions may be exaggerated for clarity of illustration. Like reference numerals refer to like elements throughout.

It will be understood that although the terms “first” and “second” are used to describe various elements, these elements should not be limited by these terms. These terms are only used to distinguish one element from another element.

In the following description of embodiments, the terms of a singular form may include plural forms unless the context clearly indicates otherwise.

It will be further understood that the terms “include,” “include,” “including,” or “including” specify a property, a region, a fixed number, an operation, a process, an element, a component, and a combination thereof but do not exclude other properties, regions, fixed numbers, operations, processes, elements, components, and combinations thereof.

As used herein, the term “and/or” includes any and all combinations of one or more of the associated listed items. Expressions such as “at least one of,” when preceding a list of elements, modify the entire list of elements and do not modify the individual elements of the list.

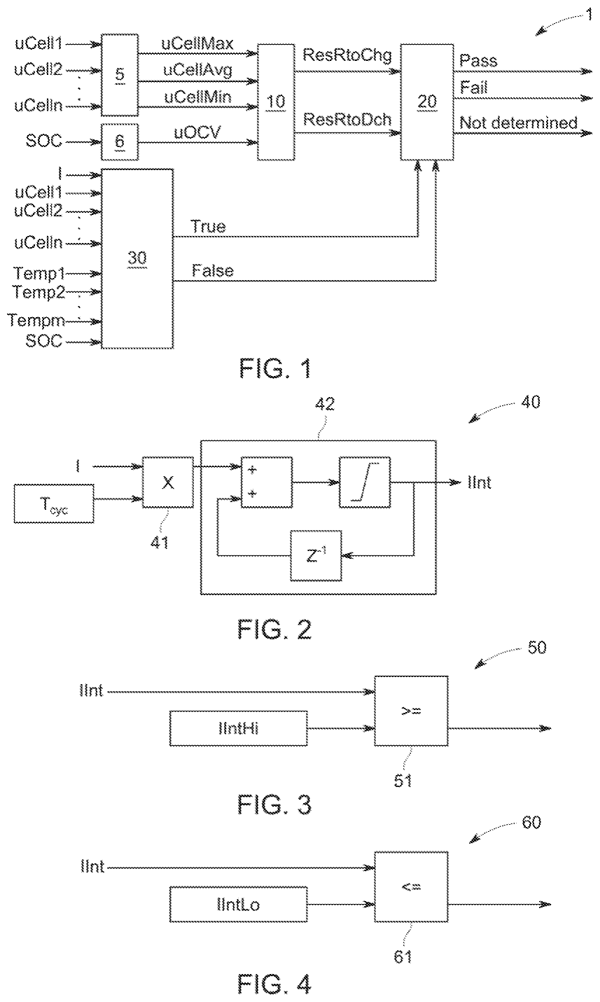

FIG. 1 shows a method and a corresponding detector 1 for detecting inhomogeneous cell performance of a battery system having a plurality of electrically interconnected battery cells.

In the following, the method and the corresponding detector 1 are simultaneously described. In general, the detector 1 is configured to perform the method for detecting inhomogeneous cell performance of the battery system as described in the following.

The method according to the present example embodiment includes determining a charging resistance ratio ResRtoChg. The charging resistance ratio ResRtoChg is the ratio of a maximum cell charging resistance ResChgMax of a battery cell among a plurality of battery cells and an average cell charging resistance ResChgAvg of the plurality of battery cells, each determined in response to a charging current I applied to the battery cells. The average cell charging resistance ResChgAvg of the plurality of battery cells may be determined as arithmetic mean.

The method may include additionally or as alternative the determining of a discharging resistance ratio ResRtoDch. The discharging resistance ratio ResRtoDch is the ratio of a maximum cell discharging resistance ResDchMax of a battery cell among a plurality of battery cells and the average cell discharging resistance ResDchAvg of the battery cells, each determined in response to a discharging current I applied to the battery cells. The charging current and the discharging current have the same reference sign, but embodiments may also include cases in which they have different magnitude. The average cell discharging resistance ResDchAvg may be determined by an arithmetic mean.

In an example embodiment, the maximum cell discharging resistance ResDchMax is the discharging resistance of one particular cell that has the highest discharging resistance among the plurality of cells, and the maximum cell charging resistance ResChgMax is the charging resistance of one particular cell that has the highest charging resistance among the plurality of cells.

Referring to FIG. 1, the detector 1 may include a first voltage determiner 5, a second voltage determiner 6, a third determiner 10, a diagnoser 20, and a condition checker 30.

The third determiner 10 may be configured to determine at least one of the above-defined resistance ratios ResRtoChg, ResRtoDch. The third determiner 10 may be configured to transmit signals indicative of the at least one of the determined resistance ratios ResRtoChg, ResRtoDch to the diagnoser 20, as shown in FIG. 1.

Based on the determined resistance ratios ResRtoChg, ResRtoDch, the method includes determining that the battery system is in a degraded ageing state when at least one of the determined charging resistance ratio ResRtoChg and/or the determined discharging resistance ratio ResRtoDch is above a predetermined threshold value. The diagnoser 20, as shown in FIG. 1, is configured to perform such determination. A control signal indicating that the battery system is in a degraded ageing state may be generated, as is indicated by the signal “Fail” in FIG. 1.

Further, the method includes the determining that the battery system is in a non-degraded ageing state when none of the determined charging resistance ratio ResRtoChg and/or the determined discharging resistance ratio ResRtoDch is above the predetermined threshold value. In such case, a control signal indicating that the battery system is in a non-degraded ageing state is generated by the diagnoser 20, as indicated by the signal “Pass” in FIG. 1. In the present example embodiment, the predetermined threshold value is above 1, e.g., 2, but embodiments may use a different threshold value.

Example embodiments may also include the cases where only one of the resistance ratios is determined, which is used alone for diagnosis. In an example embodiment, both are used to provide an early identification of ageing when only one of the ratios is at a given time above the threshold, see below.

The number of battery cells may be 4, 8, 12, 16, but the number may be varied. The used resistance ratios as defined are highly sensitive for rapid ageing of an individual battery cell or a small group of cells among a plurality of cells, e.g., due to local high temperature exposure or high self-discharge, e.g., due metallic contamination or dendrites growth caused by lithium plating. Thus, inhomogeneous cell performance and the above error modes are readily detected. Further, embodiments may identify ageing in charging and discharging directions. For example, a discharging resistance ratio may be within the allowable range, but the charging resistance ratio may already be above the threshold such that early identification is provided.

The determining of the charging resistance ratio ResRtoChg may be based on a determined average cell voltage uCellAvg, a determined average open circuit voltage uOCV and a determined maximum cell voltage uCellMax among a plurality of cell voltages uCell1, uCell2, . . . , uCelln of the battery system. Further, additionally or as alternative, the determining of the discharging resistance ratio ResRtoDch may be based on a determined average cell voltage uCellAvg, a determined average open circuit voltage uOCV and a determined minimum cell voltage uCellMin among a plurality of cell voltages uCell1, uCell2, . . . , uCelln of the battery system.

The first voltage determiner 5, as shown in FIG. 1, may be configured to determine the maximum cell voltage uCellMax, the minimum cell voltage uCellMin and the average cell voltage uCellAvg. The first voltage determiner 5 may be configured to transmit a signal indicative of the determined voltages to the third determiner 10, as shown in FIG. 1. The determining of the maximum cell voltage uCellMax, the average cell voltage uCellAvg, and the minimum cell voltage uCellMin may be based on measured individual cell voltages uCell1, uCell2, . . . , uCelln of the battery cells. These cell voltages may be determined by corresponding voltage sensors, and signally transmitted to the first voltage determiner 5. Arithmetic means may be used for determining the average cell voltages. Maximum and minimum cell voltage may be identified as the highest and lowest voltage from all cells, respectively. The measurement of the cell voltages may be performed synchronously to aid comparability.

The second voltage determiner 6 may be configured to determine the average open circuit voltage uOCV based on a determined average state of charge SOC, as shown in FIG. 1. The second voltage determiner 6 may generate a signal indicative of the average open circuit voltage uOCV, and transmit the signal to the third determiner 10. The state of charge SOC may be determined by a general method and transmitted to the second voltage determiner 6.

The third determiner 10 may be configured to determine the charging resistance ratio ResRtoChg by calculating the fraction (uCellMax−uOCV)/(uCellAvg−uOCV). Further, additionally or alternatively, the third determiner 10 may be configured to determine the discharging resistance ratio ResRtoDch by calculating the fraction (uOCV−uCellMin)/(uOCV−uCellAvg) without making explicit use of the current I, indicating the robustness of the present example embodiment towards low currents.

The condition checker 30 may be configured to determine at least one influence quantity for the determination of the charging resistance ratio ResRtoChg and/or the discharging resistance ratio ResRtoDch, and determining if the at least one influence quantity fulfills a limit condition. The influence quantity may affect the quality of the determination. In such case, the detection may perform the operations of determining that the battery system in a non-degraded state or in a degraded state only when the limit condition for the influence quantity is fulfilled.

For example, the condition checker 30 may be configured to generate a signal indicating that the condition or the conditions are fulfilled. Such a signal may be referred to as “True”, as shown in FIG. 1. When more than one condition is checked, the signal may be referred to as “True” only when all conditions are fulfilled. In the opposite case, the condition checker 30 may be configured to generate a signal indicating that the at least one condition is not fulfilled. Such signal may be hereby referred to as “False”. The condition checker 30 may be configured to transmit these signals to the diagnoser 20.

Then, in the case of a “True” signal received by the diagnoser 20, the diagnoser 20 may be configured to perform the determination as described above. In case of a “False” signal received by the diagnoser 20, the diagnoser 20 may be configured to generate a signal indicating that a determination could not be determined. The determination as described above may then be effectively prevented. Thereby, the quality of the determination of the resistance ratios may be ensured.

The condition checker 30 may be configured to receive several system quantities in order to check various limit conditions. In each of the following FIGS. 2 to 9, according to example embodiments, several condition check sub elements 40, 50, 60, 70, 80, 90, 100, 110 are described. Each of the condition check sub elements 40, 50, 60, 70, 80, 90, 100, 110 as described in the following FIGS. 2 to 9 are configured to check a particular limit condition. The condition checker 30 may include one, or more than one, or any combination of the condition check sub elements 40, 50, 60, 70, 80, 90, 100, 110 as described in the following with respect to each of the FIGS. 2 to 9.

FIGS. 2 to 4 show an example method operation wherein the at least one influence quantity includes an integrated current IInt.

For determination of integrated current IInt, an integrator 40 may be provided. The integrator 40 may be configured to receive an applied current I. The integrator 40 may include a multiplier 41 configured to multiply the current I with a cycle time Tcyc, e.g., for dimensional normalization but this operation may be omitted in other embodiments. The integrator 40 may include a limited integrator 42. The limited integrator 42 may be configured to integrate the current I over time resulting in an integrated current IInt within an upper and lower limit.

In FIGS. 3 and 4, the conditions are illustrated. In FIG. 3 a first integrated current condition checker 50 may be provided, which may include a first current condition comparator 51. The limit condition may be fulfilled when a determined integrated charging current IInt is equal to or above a charging current limit IIntHi. The integrated charging current IInt limit may be, e.g., between 20 A·s and 30 A·s.

In FIG. 4 a second integrated current condition checker 60 may be provided, which may include a second current condition comparator 61. The limit condition may be fulfilled when a determined integrated discharging current IInt is equal or below a discharging current limit IIntLo. The integrated discharging current limit IIntLo may be, e.g., between −20 A·s and −30 A·s. By the conditions of FIGS. 3 and 4, a defined state of the battery system may be reached before performing the measurement and sufficient charge reversal have been taken place.

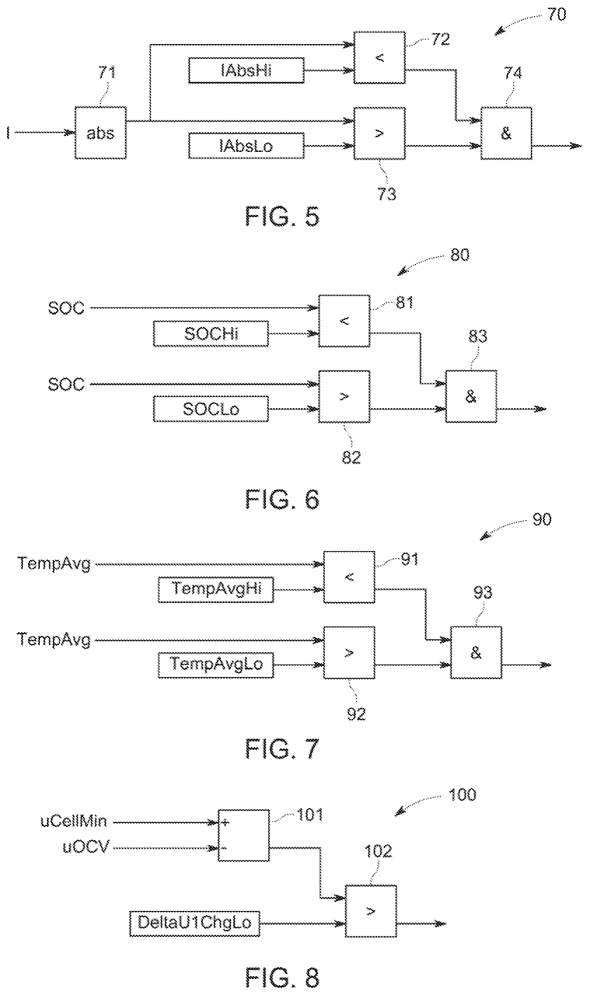

FIG. 5 shows another example method operation wherein the at least one influence quantity includes a charging current I and/or discharging current I.

In the present example embodiment, a current condition checker 70 may be provided. The current condition checker 70 may be configured to receive the determined charging current I and/or the discharging current I as input. A modulus or absolute value operator 71 may be provided to determine the modulus of the current I. A first current comparator 72 may be provided and configured to determine if the modulus of the current I is below an upper current limit IAbsHi. A second current comparator 73 may be provided and configured to determine if the modulus of the current I is above a lower current limit IAbsLo. An and-operator 74 may be configured to receive the output signals of the comparators 72, 73 and configured to determine whether the modulus of the determined current I is both between a lower current limit IAbsLo and an upper current limit IAbsHi, in which case the limit condition may be fulfilled. In other embodiments, only a lower current limit may be used. The lower current limit IAbsLo may be substantially lower than for a general cell resistance determination, e.g., IAbsLo may be 5 A or 10 A.

FIG. 6 shows another example method operation wherein the at least one influence quantity includes a determined state of charge SOC.

In the present example embodiment, a state of charge condition checker 80 may be provided. The state of charge condition checker 80 may be configured to receive the state of charge SOC of the battery cells. The state of charge condition checker 80 may include a first state of charge comparator 81. The first state of charge comparator 81 may be configured to determine if the state of charge SOC is below an upper state of charge limit SOCHi. The state of charge condition checker 80 may include a second state of charge comparator 82. The second state of charge comparator 82 may be configured to determine if the state of charge SOC is above a lower state of charge limit SOCLo.

An and-operator 83 may be configured to receive the output signals of the comparators 81, 82 and configured to determine that the state of charge SOC is between a lower state of charge limit SOCLo and an upper state of charge limit SOCHi, in which case the limit condition may be fulfilled. This condition may ensure the quality of the resistance ratio determination.

FIG. 7 shows another example method operation wherein the at least one influence quantity includes a determined average temperature TempAvg.

In the present example embodiment, the determined average temperature TempAvg is an average of measured cell temperatures Temp1, Temp2, . . . , Tempm at respective battery cells. In the present example embodiment, a temperature condition checker 90 may be provided. The temperature condition checker 90 may be configured to receive the average temperature TempAvg of the battery cells. The temperature condition checker 90 may include a first temperature comparator 91. The first temperature comparator 91 may be configured to determine if the temperature TempAvg is below an upper temperature limit TempAvgHi. The temperature condition checker 90 may include a second temperature comparator 92. The second temperature comparator 92 may be configured to determine if the temperature TempAvg is above a lower temperature limit TempAvgLo. An and-operator 93 may be configured to receive the output signals of the comparators 91, 92 and configured to determine that the temperature TempAvg is between a lower temperature limit TempAvgLo and an upper temperature limit TempAvgHi, in which case the limit condition may be fulfilled. In an example embodiment, a boundary for the lower temperature limit TempAvgLo may be −20° C., which may be lower than a general cell resistance determination. In an example embodiment, a boundary for the upper temperature limit TempAvgHi may be 55° C. A temperature in excess of the upper temperature limit may lead to simultaneous degradation and thus may not be useful as a signature of inhomogeneous cell performance.

FIG. 8 shows another example method operation, in which the at least one influence quantity includes a first charging voltage difference between the minimum cell voltage uCellMin among a plurality of cell voltages uCell1, uCell2, . . . , uCelln of the battery system and the average open circuit voltage uOCV upon charging.

In the present example embodiment, a first voltage difference condition checker 100 may be provided. The first voltage difference condition checker 100 may be configured to receive the minimum cell voltage uCellMin among a plurality of cell voltages uCell1, uCell2, . . . , uCelln and the average open circuit voltage uOCV.

The first voltage difference condition checker 100 may include a subtracter 101 configured to determine the difference between the minimum cell voltage uCellMin among a plurality of cell voltages uCell1, uCell2, . . . , uCelln of the battery system and the average open circuit voltage uOCV upon charging. The first voltage difference condition checker 100 may include a first voltage comparator 102. The first voltage comparator 102 may be configured to determine if the first charging voltage difference is above a first voltage charging difference limit DeltaU1ChgLo. The limit condition may be fulfilled when the first charging voltage difference is above the first voltage difference limit DeltaU1ChgLo. The first voltage difference limit DeltaU1ChgLo may be, e.g., 20 mV, 30 mV or 50 mV.

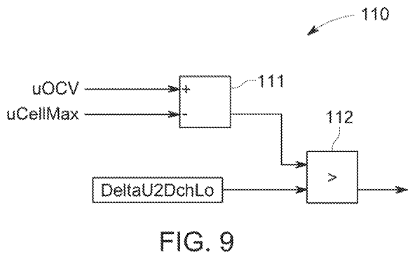

FIG. 9 shows yet another example method operation wherein the at least one influence quantity includes a second discharging voltage difference between the average open circuit voltage uOCV upon discharging and the maximum cell voltage uCellMax among a plurality of cell voltages uCell1, uCell2, . . . , uCelln.

In the present example embodiment, a second voltage difference condition checker 110 may be provided. The second voltage difference condition checker 110 may be configured to receive the maximum cell voltage uCellMax among a plurality of cell voltages uCell1, uCell2, . . . , uCelln and the average open circuit voltage uOCV upon discharging.

The second voltage difference condition checker 110 may include a subtracter 111 configured to determine the difference between the average open circuit voltage uOCV upon discharging and the maximum cell voltage uCellMax among a plurality of cell voltages uCell1, uCell2, . . . , uCelln of the battery system. The second voltage difference condition checker 110 may include a second voltage comparator 112. The second voltage comparator 112 may be configured to determine if the second voltage difference is above a second discharging voltage difference limit DeltaU2DchLo. The limit condition may be fulfilled when the second discharging voltage difference is above the second discharging voltage difference limit DeltaU2DchLo. The second voltage difference limit DeltaU2DchLo may be, e.g., 20 mV, 30 mV or 50 mV.

The determining of the charging resistance ratio ResRtoChg and/or the discharging resistance ratio ResRtoDch may be repeated at every drive cycle.

The above-described influence quantities refer to example influence quantities, but further influence quantities may be used.

In various example embodiments, the condition checker 30 may include any one of the described condition check sub elements 40, 50, 60, 70, 80, 90, 100, 110 corresponding to the examples described above in connection with FIGS. 2 to 9. In various example embodiments, the condition checker 30 may a single one of or a plurality of condition check sub elements 40, 50, 60, 70, 80, 90, 100, 110 selected among the condition check sub elements 40, 50, 60, 70, 80, 90, 100, 110 of the FIGS. 2 to 9. The condition checker 30 may include various combinations of the condition check sub elements 40, 50, 60, 70, 80, 90, 10, 110. The selection may depend on the influence quantities to be taken into account to ensure the quality of the determination.

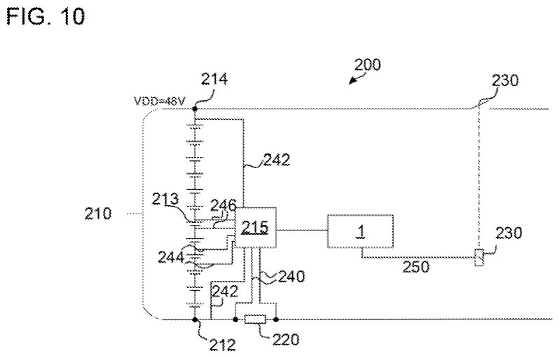

FIG. 10 shows a battery system 200 according to an example embodiment.

The battery system 200 may include a plurality of battery cells 213. For example, the plurality of battery cells 213 may form a battery cell stack 210 generating a system voltage VDD which may be, e.g., 48 V. A first node 212 may correspond to a ground or negative polarity, and a second node 214 may be on the high voltage VDD. The number of battery cells 213 may be, e.g., 4, 8 or 12, the latter as in the present example. Each of the battery cells 213 may provide a voltage of, e.g., 4 V, by way of example. The battery cells 213 may be arranged in series, in parallel, or in other configurations.

The battery system 200 may include one or more sensors 215 to sense the input quantities as used in the context of the previous FIGS. 1 to 9, for example, cell voltages, cell temperatures, charging/discharging current, as discussed above. For example, the sensor(s) 215 may be implemented as elements of an analog front end, AFE. For example, voltage measurement lines for the system voltage VDD, temperature measurement lines 246 for a cell temperature, and cell voltage measurement lines 244 for cell voltages may be provided to sense the input quantities. A shunt 220 may be included along with current measurement lines 240 to obtain signals indicative of the current via the shunt 220. Further, the battery system 200 may include the detector 1 for detecting inhomogeneous cell performance according to the various example embodiments as described above. The detector 1 may receive the measured quantities from the sensor(s) 215, e.g., from the AFE. In another implementation, the sensor(s) 215 may be part of the detector 1. The detector 1 may be configured to generate a control signal 250, e.g., to control a power switch 230 or for replacement of individual battery cells or other applications, based on a determination result of determining the inhomogeneous cell performance.

The electronic or electric devices and/or any other relevant devices or components according to embodiments described herein may be implemented utilizing any suitable hardware, firmware (e.g. an application-specific integrated circuit), software, or a combination of software, firmware, and hardware. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate. Further, the various components of these devices may be a process or thread, running on one or more processors, in one or more computing devices, executing computer program instructions and interacting with other system components for performing the various functionalities described herein. The computer program instructions may be stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, the functionality of various computing devices may be combined or integrated into a single computing device, or the functionality of a particular computing device may be distributed across one or more other computing devices.

By way of summation and review, a static control of battery power output and charging may be replaced by a steady exchange of information between the battery system and the controllers of the electrical consumers. This information may include the battery system's actual state of charge, potential electrical performance, charging ability, and internal resistance, as well as actual or predicted power demands or surpluses of the load/consumers.

A battery system may include a battery control for processing the aforementioned information. The battery control may include controllers of the various electrical consumers and may contain suitable internal communication busses, e.g., a SPI or CAN interface. The battery control may communicate with battery submodules, e.g., with cell supervision circuits or cell connectors and sensors. Thus, the battery control may be provided for managing the battery stack, such as by protecting the battery from operating outside its safe operating state, monitoring its state, calculating secondary data, reporting that data, controlling its environment, authenticating it, and/or balancing it.

A diagnosis function may be provided for determining the present ageing status of a battery system. The ageing status of a battery may be described by the capacity, which is related to the energy content of the battery, on the one hand, and by the internal resistance, which is related to the power ability of the battery, on the other hand. Embodiments may be used to determine ageing mechanisms using the internal resistance. To be able to predict the present power ability of the system based on the determined cell resistance, a current may need to reach a certain amount. During usage of the battery, the cells may be subject to ageing and the resistance may grow. Also, at lower temperatures, the resistance may be higher compared to at a standard condition of, e.g., 25° C. Therefore, the condition for the amount of current may be significant because the cell voltage limit may be reached prior to a successful resistance determination.

The internal resistance of a cell of a battery system may generally be determined according to testing methods such as those described in ISO standards. The internal resistance may be used to characterize the power ability of the cell. The internal resistance may be dependent on temperature, state of charge, applied current, duration of applied current, ageing status of the cell, and previous usage of the cell. The internal resistance may be used to characterize the ageing status of the cell when a defined pulse duration and the reference ageing behavior according to temperature, state of charge, applied current, etc. are precisely known.

For expected normal behavior, the internal resistance may only change slowly. The resistance growth may depend on the usage of the battery, but assuming a 30% increase over 6 years, this may be a slowly changing parameter. Therefore, the determination frequency may be set to be low, e.g., only once every quarter of a year, although the determination accuracy should be high.

A different situation occurs when unexpected limitations, e.g., during usage in the powertrain of a vehicle, affect the battery system. Rapid performance degradation due to ageing may occur, e.g., in a longer vehicle parking situation. A possible observed error mode may be the exposure of the cell or some cells to a very high temperature, e.g., to 60° C., which may cause rapid increase of internal resistance due to electrolyte decomposition. Another possible observed error may be a high self-discharge, e.g., caused by dendrites growth in response to lithium plating due to battery usage or metallic particle contamination during cell manufacturing.

As described above, embodiments may provide a method of detecting inhomogeneous cell performance. The method may allow for high availability and high testing frequency, may be applicable for low current conditions, may identify weakly performing individual cells among a plurality of battery cells.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

### REFERENCE SIGNS

1 detector
5 first voltage determiner
6 second voltage determiner
10 determiner
20 diagnoser
30 condition checker
40 integrator
41 multiplier
42 limited integrator
50 first integrated current condition checker
51 first integrated current comparator
60 second integrated current condition checker
61 second integrated current comparator
70 current condition checker
71 modulus operator
72 first current comparator
73 second current comparator
74 and-operator
80 state of charge condition checker
81 first state of charge comparator
82 second state of charge comparator
83 and-operator
90 temperature condition checker
91 first temperature comparator
92 second temperature comparator
93 and-operator
100 first voltage difference condition checker
101 subtracter
102 first voltage comparator
110 second voltage difference condition checker
111 subtracter
112 second voltage comparator
200 battery system
210 battery cell stack
212 first node
213 battery cell
214 second node
215 sensor
220 shunt
230 power switch
240 current measurement line
242 voltage measurement line
244 cell voltage measurement line
246 temperature measurement line
250 control signal
VDD system voltage
uCell1, uCell2, . . . , uCelln cell voltage
uCellAvg average cell voltage
Temp1, Temp2, Tempm cell temperature
TempAvg average temperature
ResRtoChg charging resistance ratio
ResChgMax maximum cell charging resistance
ResChgAvg average cell charging resistance
ResRtoDch discharging resistance ratio
ResDchMax maximum cell discharging resistance
ResDchAvg average cell discharging resistance
I charging current/discharging current
IAbsLo lower current limit
IAbsHi upper current limit
IInt integrated current
IIntHi charging integrated current limit
IIntLo discharging integrated current limit
SOC average state of charge
SOCLo lower state of charge limit
SOCHi upper state of charge limit
uOCV average open circuit voltage
TempAvg average temperature
TempAvgLo lower temperature limit
TempAvgHi upper temperature limit
DeltaU1ChgLo first charging voltage difference limit
DeltaU2DchLo second discharging voltage difference limit

What is claimed is:

1. A method for detecting inhomogeneous cell performance of a battery system having a plurality of battery cells, the method comprising:
determining a charging resistance ratio, which is a ratio of a maximum cell charging resistance of a battery cell among the plurality of battery cells and an average cell charging resistance of the plurality of battery cells, each determined in response to a charging current applied to the plurality of battery cells; and/or
determining a discharging resistance ratio, which is a ratio of a maximum cell discharging resistance of a battery cell among the plurality of battery cells and an average cell discharging resistance of the plurality of battery cells, each determined in response to a discharging current applied to the plurality of battery cells; and
determining that the battery system is in a degraded ageing state when at least one of the determined charging resistance ratio and/or the determined discharging resistance ratio is above a predetermined threshold value; and
determining that the battery system is in a non-degraded ageing state when none of the determined charging resistance ratio and/or the determined discharging resistance ratio is above the predetermined threshold value.

2. The method of claim 1, wherein:
the determining of the charging resistance ratio is based on a determined average cell voltage, a determined average open circuit voltage, and a determined maximum cell voltage among a plurality of cell voltages of the battery system, and
the determining of the discharging resistance ratio is based on the determined average cell voltage, the determined average open circuit voltage, and a determined minimum cell voltage among the plurality of cell voltages of the battery system.

3. The method as claimed in claim 2, wherein the average open circuit voltage is determined based on a determined average state of charge.

4. The method as claimed in claim 2, wherein determining the maximum cell voltage, the average cell voltage, and the minimum cell voltage is based on measured individual cell voltages of the plurality of battery cells.

5. The method as claimed in claim 2, wherein:
determining the charging resistance ratio includes calculating a fraction (uCellMax−uOCV)/(uCellAvg−uOCV), and
determining the discharging resistance ratio includes calculating a fraction (uOCV−uCellMin)/(uOCV−uCellAvg),
wherein:
uCellMax is the determined maximum cell voltage,
uOCV is the determined average open circuit voltage,
uCellAvg is the determined average cell voltage, and
uCellMin is the determined minimum cell voltage.

6. The method as claimed in claim 1, further comprising:
determining at least one influence quantity for the determination of the charging resistance ratio and/or the discharging resistance ratio,
determining if the at least one influence quantity fulfills a limit condition, and
determining that the battery system in a non-degraded state or in a degraded state only when the limit condition is fulfilled.

7. The method as claimed in claim 6, wherein:
the at least one influence quantity includes an integrated current, and
the limit condition is fulfilled when a determined integrated charging current is equal to or above a charging current limit and/or when an integrated discharging current is equal to or below an integrated discharging current limit.

8. The method as claimed in claim 6, wherein:
the at least one influence quantity includes a determined charging current and/or a discharging current, and
the limit condition is fulfilled when a modulus of the determined current is between a lower current limit and an upper current limit.

9. The method as claimed in claim 6, wherein:
the at least one influence quantity includes a determined average state of charge, and
the condition is fulfilled when the determined average state of charge is between a lower state of charge limit and an upper state of charge limit.

10. The method as claimed in claim 6, wherein:
the at least one influence quantity includes a determined average temperature, and
the limit condition is fulfilled when the average temperature is between a lower temperature limit and an upper temperature limit.

11. The method as claimed in claim 6, wherein:
the at least one influence quantity is:
a first charging voltage difference between a minimum cell voltage among a plurality of cell voltages of the battery system and an average open circuit voltage upon charging, and/or
a second discharging voltage difference between an average open circuit voltage upon discharging and a maximum cell voltage among a plurality of cell voltages, and
the limit condition is fulfilled when the first charging voltage difference is above a first charging voltage difference limit and/or the second discharging voltage difference is above a second discharging voltage difference limit.

12. The method as claimed in claim 1, wherein the determining of the charging resistance ratio and/or the discharging resistance ratio is repeated at every drive cycle.

13. A detector for detecting inhomogeneous cell performance of a battery system having a plurality of battery cells, wherein the detector is configured to perform the method as claimed in claim 1.

14. A battery system, comprising:
a plurality battery cells; and
the detector as claimed in claim 13.

15. An electrical vehicle, comprising the battery system as claimed in claim 14.
